(19) United States
(12) Patent Application Publication
(10) Pub. No.: US 2023/0359373 A1
(43) Pub. Date: Nov. 9, 2023

(54) SELECTIVE REFRESH FOR MEMORY DEVICES

(71) Applicant: QUALCOMM Incorporated, San Diego, CA (US)

(72) Inventors: Engin Ipek, San Diego, CA (US); Hamza Omar, San Diego, CA (US); Bohuslav Rychlik, San Diego, CA (US); Saumya Ranjan Kuanr, San Diego, CA (US); Behnam Dashtipour, San Diego, CA (US); Michael Hawjing Lo, San Diego, CA (US); Jeffrey Gemar, San Diego, CA (US); Matthew Severson, Austin, TX (US); George Patsilaras, San Diego, CA (US); Andrew Edmund Turner, San Diego, CA (US)

(21) Appl. No.: 17/661,810

(22) Filed: May 3, 2022

(51) Int. Cl. G06F 3/06

(52) U.S. Cl. CPC G06F 3/0632; G06F 3/0604; G06F 3/0673

(57) ABSTRACT

Selective refresh techniques for memory devices are disclosed. In one aspect, a memory device that is used with an application that has frequent repeated read or write commands to certain memory segments may be able to set a flag or similar indication that exempts these certain memory segments from being actively refreshed. By exempting these memory segments from being actively refreshed, these memory segments are continuously available, thereby improving performance. Likewise, because these memory segments are so frequently the subject of a read or write command, these memory segments are indirectly refreshed through the execution of the read or write command.

### BACKGROUND

### I. Field of the Disclosure

The technology of the disclosure relates generally to memory systems that require memory cell refreshes.

### II. Background

Computing devices abound in modern society, and more particularly, mobile communication devices have become increasingly common. The prevalence of these mobile communication devices is driven in part by the many functions that are now enabled on such devices. Increased processing capabilities in such devices means that mobile communication devices have evolved from pure communication tools into sophisticated mobile entertainment centers, thus enabling enhanced user experiences. Access to such functionality is usually dependent on having a memory system interoperate with a control system to store instructions and data. One popular format of memory is the low power double data rate (LPDDR) synchronous dynamic random access memory (SDRAM) standard. JEDEC is the standards setting body for LPDDR and has promulgated various versions of the standard, with LPDDR5 updated in June of 2021. The existence of such standards provides opportunities for improvements and innovation, and such innovation may be used in extant standards or prospective standards or other implementations.

### SUMMARY

Aspects disclosed in the detailed description include selective refresh techniques for memory devices. In particular, a memory device that is used with an application that has frequent repeated read or write commands to certain memory segments may be able to set a flag or similar indication that exempts these certain memory segments from being actively refreshed. By exempting these memory segments from being actively refreshed, these memory segments are continuously available, thereby improving performance. Likewise, because these memory segments are so frequently the subject of a read or write command, these memory segments are indirectly refreshed through the execution of the read or write command.

In this regard in one aspect, an integrated circuit (IC) is disclosed. The IC includes a memory bus interface configured to be coupled to a memory device through a memory bus. The IC also includes a memory controller coupled to the memory bus interface. The memory controller is configured to instruct the memory device to put active data in a memory segment. The memory controller is also configured to set a segment mask for the memory segment.

In another aspect, an IC is disclosed. The IC includes a memory bus interface configured to be coupled to a memory controller through a memory bus. The IC also includes a memory bank coupled to the memory bus interface. The memory bank is configured to receive a sequence of commands to put active data in a memory segment. The memory bank is also configured to set a segment mask for the memory segment.

In another aspect, a method for managing memory is disclosed. The method includes instructing a memory device to put active data in a memory segment. The method also includes setting a segment mask for the memory segment.

### BRIEF DESCRIPTION OF THE DRAWINGS

FIG. 1 is a block diagram of an exemplary mobile computing device that may include memory elements that operate according to a JEDEC memory standard;

FIG. 2A is a block diagram of a memory device configured to comply with a low power double data rate (LPDDR) version 5 standard (LPDDR5);

FIG. 2B is a block diagram of an LPDDR5 channel configuration showing how banks are arranged within the channel;

FIG. 3 is a block diagram of a system on a chip (SoC) working with a memory device over a memory bus according to an exemplary aspect of the present disclosure;

FIG. 4 is a flowchart illustrating an exemplary process for handling selective refresh within a memory device; and

FIG. 5 is a flowchart illustrating an alternate exemplary process for handling selective refresh within a memory device.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed in the detailed description include selective refresh techniques for memory devices. In particular, a memory device that is used with an application that has frequent repeated read or write commands to certain memory segments may be able to set a flag or similar indication that exempts these certain memory segments from being actively refreshed. By exempting these memory segments from being actively refreshed, these memory segments are continuously available, thereby improving performance. Likewise, because these memory segments are so frequently the subject of a read or write command, these memory segments are indirectly refreshed through the execution of the read or write command.

In a further exemplary aspect, the memory device may be a low power double data rate (LPDDR) memory device that relies on dynamic random access memory (DRAM), that stores data by holding a charge within a cell formed from a plurality of transistors. The charge fades with time and must be refreshed or the data indicated by the charge is lost or corrupted.

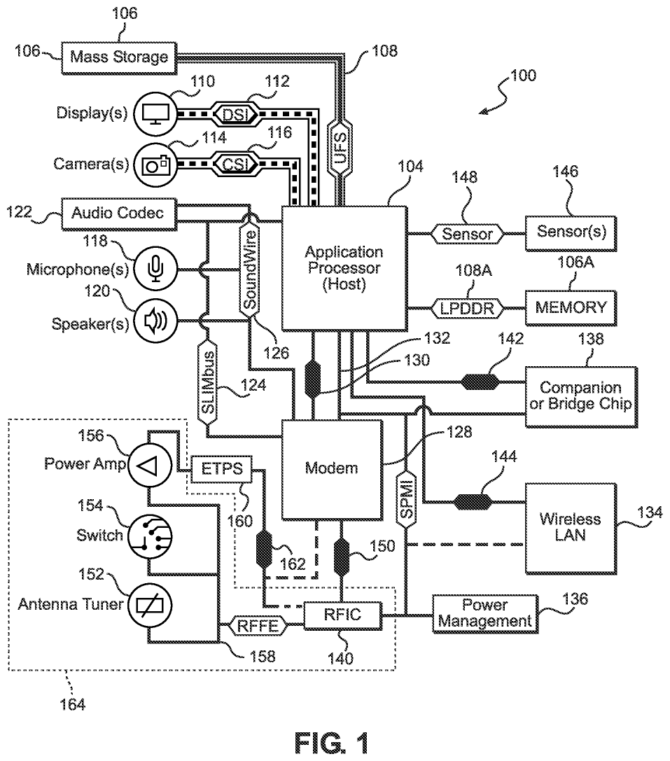

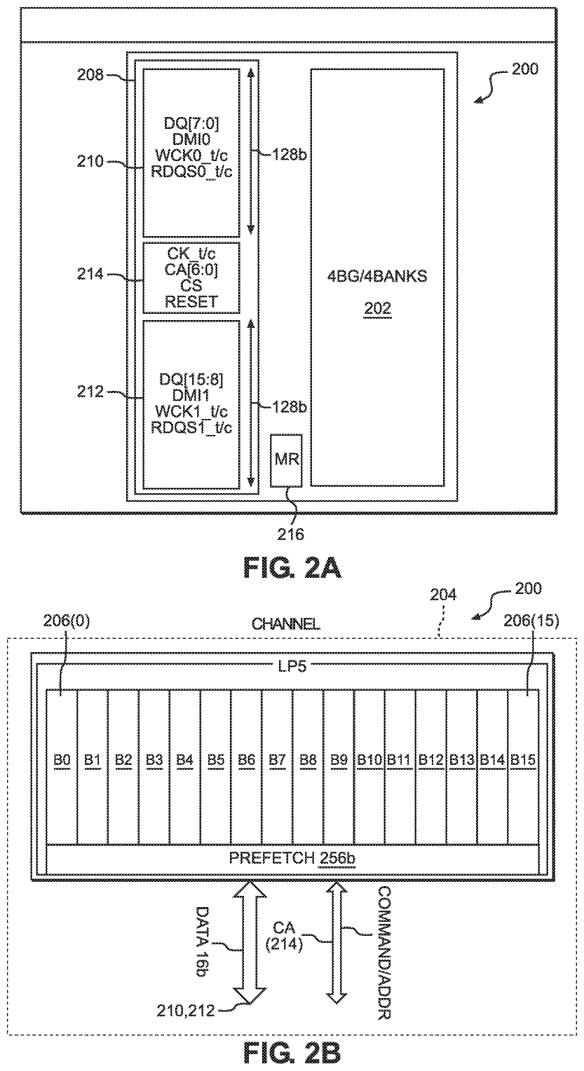

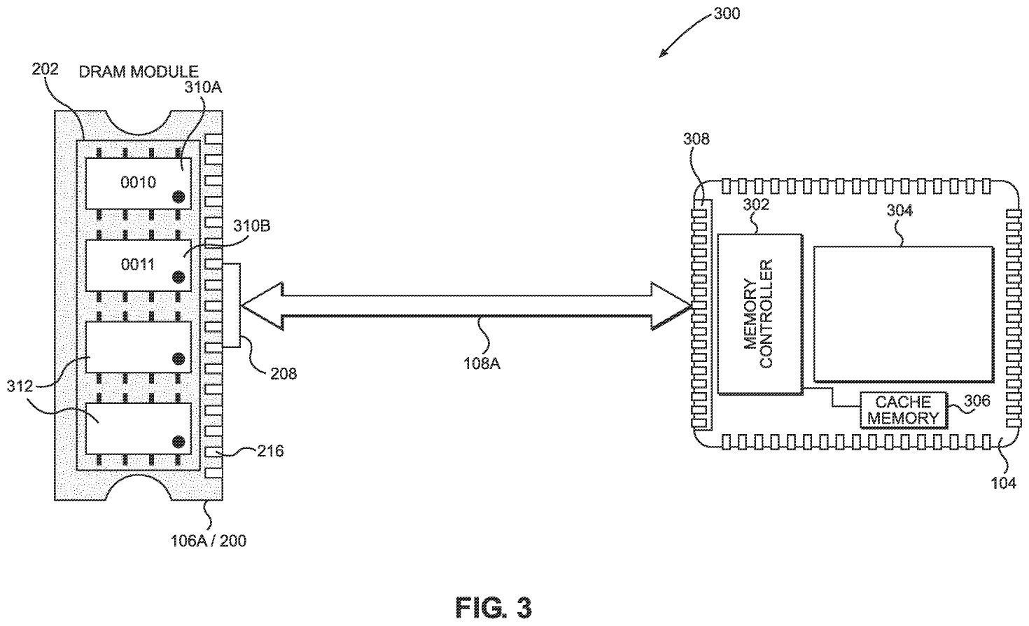

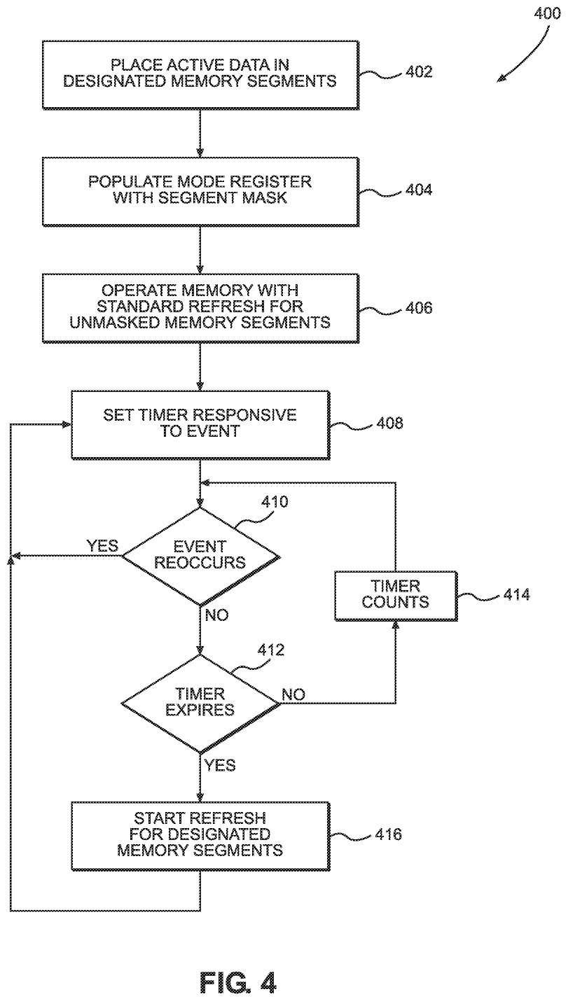

Before addressing particular aspects of the present disclosure, an overview of a computing device is provided in FIG. 1 showing where a memory device may be used within such a computing device. Additional details about a memory device and a memory controller are provided with reference to FIGS. 2A-3. The discussion of exemplary aspects of the present disclosure begins below with reference to FIG. 4.

As an initial bit of nomenclature, it should be appreciated that double data rate (DDR) is a term of art within the JEDEC specifications and the memory world in general. As used herein, DDR is defined to be a signaling technique that uses both the falling and rising edges of the clock signal. This use of both edges is independent of frequency, and changes (e.g., doubling) in frequency do not fall within DDR unless both edges are used. Also contrast DDR with single data rate (SDR) which can transfer data on a rising edge or a falling edge, but not both.

FIG. 1 is a system-level block diagram of an exemplary mobile terminal 100 such as a smart phone, mobile computing device tablet, or the like. While a mobile terminal having a LPDDR bus is particularly contemplated as being capable of benefiting from exemplary aspects of the present disclosure, it should be appreciated that the present disclosure is not so limited and may be useful in any system having comparable memory buses.

With continued reference to FIG. 1, the mobile terminal 100 includes an application processor 104 (sometimes referred to as a host or system on a chip SoC) that communicates with a mass storage element 106 through a universal flash storage (UFS) bus 108. Additionally, the application processor 104 may communicate with a memory device 106A through an LPDDR bus 108A. While it is particularly contemplated that exemplary aspects of the present disclosure apply to LPDDR versions 4 or 5 (i.e., LPDDR4 or LPDDR5) and other emerging memory standards, the present disclosure is not so limited and may apply to other memory buses. It should be appreciated that the application processor 104 includes a bus interface configured to interoperate with the memory buses of the present disclosure such as the LPDDR bus 108A. Additionally, there may be a memory controller circuit (not shown in FIG. 1) within the application processor 104 that implements aspects of the present disclosure. Likewise, the memory device 106A may have a bus interface and some form of control circuit that processes commands received from the LPDDR bus 108A and accesses memory cells within the memory device 106A.

The application processor 104 may further be connected to a display 110 through a display serial interface (DSI) bus 112 and a camera 114 through a camera serial interface (CSI) bus 116. Various audio elements such as a microphone 118, a speaker 120, and an audio codec 122 may be coupled to the application processor 104 through a serial low-power interchip multimedia bus (SLIMbus) 124. Additionally, the audio elements may communicate with each other through a SOUNDWIRE bus 126. A modem 128 may also be coupled to the SLIMbus 124 and/or the SOUNDWIRE bus 126. The modem 128 may further be connected to the application processor 104 through a peripheral component interconnect (PCI) or PCI express (PCIe) bus 130 and/or a system power management interface (SPMI) bus 132.

With continued reference to FIG. 1, the SPMI bus 132 may also be coupled to a local area network (LAN or WLAN) integrated circuit (IC) (LAN IC or WLAN IC) 134, a power management integrated circuit (PMIC) 136, a companion IC (sometimes referred to as a bridge chip) 138, and a radio frequency IC (RFIC) 140. It should be appreciated that separate PCI buses 142 and 144 may also couple the application processor 104 to the companion IC 138 and the WLAN IC 134. The application processor 104 may further be connected to sensors 146 through a sensor bus 148. The modem 128 and the RFIC 140 may communicate using a bus 150.

With continued reference to FIG. 1, the RFIC 140 may couple to one or more RFFE elements, such as an antenna tuner 152, a switch 154, and a power amplifier 156 through a radio frequency front end (RFFE) bus 158. Additionally, the RFIC 140 may couple to an envelope tracking power supply (ETPS) 160 through a bus 162, and the ETPS 160 may communicate with the power amplifier 156. Collectively, the RFFE elements, including the RFIC 140, may be considered an RFFE system 164. It should be appreciated that the RFFE bus 158 may be formed from a clock line and a data line (not illustrated).

The LPDDR5 standard contemplates a memory die or memory device 200, illustrated in FIG. 2A that includes a memory block 202 having four bank groups (BG), each with four banks for a total of sixteen banks, which forms a channel 204 of banks 206(0)-206(15) (also B0-B15 as illustrated) as shown in FIG. 2B. The memory device 200 may include an interface 208 (FIG. 2A) that has a first eight DQ conductors (DQ[7:0]), a first data mask inversion conductor (DMI0), two conductors that form a first differential write clock (WCK), and a pair of conductors that form a first read data strobe (RDQS0) in a first group 210; and a second eight DQ conductors (DQ[15:8]), a second data mask inversion conductor (DMI1), two conductors that form a second differential write clock (WCK), and two conductors that form a second read data strobe (RDQS1) in a second group 212. The groups 210, 212 share a differential clock (CK), a command and address conductor(s) (CA[6:0]), a chip select conductor (CS), and a reset conductor (all shown in middle group 214). The memory device 200 further includes one or more registers, of which at least one is a mode register 216. A typical LPDDR5 memory device 200 may have: a maximum bandwidth of 12.8 gigabytes per second (GB/s), an input/output speed of 6400 megabits per second (Mbps), a maximum CK frequency of 800 megahertz (MHz), a maximum WCK frequency of 3200 MHz, a CA speed of 1600 megatransfers per second (MT/s), and operate on a non-return to zero (NRZ) signaling scheme. While banks and bank groups are specifically contemplated, they are not central to the present disclosure and may be omitted in memory devices using the present disclosure.

In practice, the memory block 202 is formed of a variety of cells (e.g., a one transistor-one capacitor (1T-1C or sometimes 1T1C)). Each cell is expected to have a retention time of sixty-four milliseconds (64 ms), and thus, every cell must be refreshed within a 64 ms window. This refresh task is broken into equally-sized refresh operations, where each refresh operation takes approximately three hundred nanoseconds (300 ns). When a cell is being refreshed, it is not available to handle traffic (e.g., read or write commands). If a read or write command to a given cell occurs while the given cell is being refreshed, traffic to the cell may stall until refresh is complete, resulting in added latency. Such latency is generally undesirable.

FIG. 3 provides some additional details of a memory system 300 shown removed from the mobile terminal 100. Specifically, the application processor 104 may include a memory controller 302. The memory controller 302 may interoperate with one or more processors 304 (one shown). The processor 304 may be, for example, a central processing unit (CPU), a video encoder, a graphics processing unit (GPU), a neural signal processor (NSP), a neural processing unit (NPU), a digital signal processor (DSP), or the like. The processor 304 may include a timer (not shown explicitly). The memory controller 302 and/or the processor 304 may work with a cache or local memory 306 to store certain information according to exemplary aspects of the present disclosure. Additionally, the application processor 104 may include a memory bus interface 308 configured to be coupled to the memory bus 108A.

The memory device 106A/200 is also configured to be coupled to the memory bus 108A through a memory bus interface such as memory bus interface 208. The memory device 106A/200 may be a DRAM module and include the memory block 202. The memory block 202 may have memory segments 310A, 310B where active data is stored. As used herein active data is data that is frequently read from or written to, and may be so used multiple times within a refresh interval. Additional details about this active data are discussed below. Additional memory segments 312 may be used for normal data.

Exemplary aspects of the present disclosure take advantage of certain types of memory usage where there is active data. Because the data is active and used, likely multiple times per refresh interval, the cells containing that data do not have to be refreshed to maintain the data. That is, each time a cell is read from, a voltage is applied that refreshes the charge on the read cell. Likewise, each time a cell is written to, a voltage is applied that places the charge on the cell. Accordingly, exemplary aspects of the present disclosure opportunistically place such active data in specific memory segments and do not issue refresh commands to those memory segments relying on the frequent use of the active data to refresh the data in those memory segments.

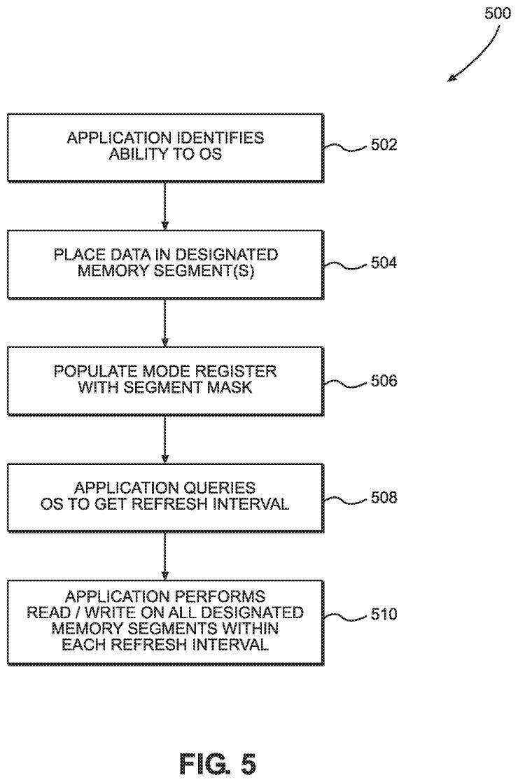

Optionally, a safety net may be used to allow data that is normally active but temporarily underutilized to be refreshed through conventional refresh techniques. More detail is provided below with reference to FIGS. 4 and 5. However, before that discussion, an exemplary use case is explored so that exemplary characteristics of active data may be examined along with examples of interruptions that may occur.

One exemplary use case is in inference workloads such as machine learning. In machine learning, there are generally two types of active data. The first type of active data is sometimes described as “weights” which are repeatedly read within a single refresh interval. These weights are used in the algorithm to weight variables used in the algorithms of the machine learning process. The second type of active data is sometimes referred to as “activations” which are repeatedly overwritten within a single refresh interval. That is, the aforementioned algorithms may generate multiple intermediate values, which are stored, used in another calculation and overwritten multiple times. In both cases, the read commands and the write commands are effectively continually refreshing the data. Using a conventional refresh command on such data is redundant and may interrupt the algorithm's use of the data because the cell is unavailable during the refresh. It should be appreciated that there are other use cases where there may be active data including streaming applications such as a camera to display or a graphics processing unit (GPU) to display.

Machine learning may be based on a client-server model such as over the Internet or through the cloud to take advantage of computers with higher processing power than might be available locally to the entity that initiates the machine learning algorithms. Because of the distributed nature of such client-server models, it is possible that there may be occasions where the client loses the communication link to the server or there are delays in the network that cause a steady stream of packets to be received intermittently. In such instances, because there are no incoming commands to the server's processor, there may gaps in use of active data. Exemplary aspects of the present disclosure provide a safety net to refresh active data in such situations even though the active data has had refresh operations suspended under the initial aspect of the present disclosure.

FIG. 4 illustrates a flowchart of a process 400 that eliminates redundant refresh commands for active data and provides an optional safety net that preserves the active data even when there is some interruption in the use of the active data. In this regard, the process 400 begins when a processor operating with an inference workload (such as machine learning) or other similar workload that has active data, determines that some data is active data. The processor 104 uses the memory controller 302 to place active data in designated memory segments (e.g., memory segments 310A, 310B) (block 402) within the memory device 200. Additionally, the memory controller 302 may populate the mode register 216 with a segment mask (block 404). In an LPDDR standard, this segment mask may take the form of a partial array auto refresh (PAAR) flag or bit that indicates to the DRAM module that segments displaying the PAAR bit are not to be refreshed. In effect, the actions of blocks 402 and 404 put the active data in specific memory segments and then flag those memory segments in a manner that causes normal refresh commands to ignore those memory segments. It should be appreciated that segment masks of this sort were originally intended to be used for memory segments that were not being used for real data. That is, there is no reason to refresh a memory segment that has no data therein, so the segment mask was used to reduce a required number of refresh commands, which reduced power consumption. Exemplary aspects of the present disclosure invert this concept and specifically apply a segment mask to a memory segment that has real data.

With continued reference to FIG. 4, the process 400 continues where the memory device 200 and the application processor 104 operate normally with standard refresh commands for unmasked memory segments (block 406). The processor 304 may set a timer responsive to an event (block 408). In an exemplary aspect, the event is the beginning of an inference workload by a machine learning algorithm. The processor 304 determines if the event reoccurs (block 410). If the answer is yes, the process 400 returns to normal operation until the event occurs again. That is, the recurrence of the event causes the timer to reset. If, however, the answer to block 410 is no, the event does not reoccur, the processor 304 determines if the timer expires (block 412). Note that the timer may be a count-down timer that expires at zero or a count-up timer that expires when a threshold is passed. If the answer to block 412 is no, then the timer counts (block 414), and the processor 304 checks for reoccurrence of the event (block 410). If, however, the answer to block 412 is yes, then the processor 304 removes the segment mask from the register and starts refreshing the previously masked segments normally (block 416).

The use of the timer in process 400 acts as the safety net to make sure that the masked segments are refreshed in the event of an interruption in the normally frequent events. By way of example, if the refresh interval is 64 ms, the timer may be 32 ms, although other values may be chosen. The value (refresh interval-timer) should be larger than a time required to refresh the masked segments. Thus, for example, if a refresh takes 10 microseconds (μs) per segment and there are ten masked segments, the time required should be 100 μs and the value of the timer may be chosen to satisfy (64 ms−timer)>100 μs. These values are exemplary only.

Instead of using the timer as described in process 400, exemplary aspects of the present disclosure may place the burden for tracking refreshing on an application that is using the memory device 200. This situation is illustrated by process 500 in FIG. 5. In particular, an operating system (OS) of the processor 304 and the application communicate to identify the masking ability of the memory device and the application's ability to control refreshing (block 502). The processor 304 places data in the designated memory segments (block 504) and populates the mode register with the segment mask (block 506).

The application may query the OS to get a refresh interval (which may be temperature dependent or vary for other reasons) (block 508). The application then reads and writes to all cells of the designated memory segments within each refresh interval (block 510) with the risk that if there is an interruption, the data may be lost.

The selective refresh techniques for memory devices according to aspects disclosed herein may be provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

Those of skill in the art will further appreciate that the various illustrative logical blocks, modules, circuits, and algorithms described in connection with the aspects disclosed herein may be implemented as electronic hardware, instructions stored in memory or in another computer readable medium wherein any such instructions are executed by a processor or other processing device, or combinations of both. The master devices, and slave devices described herein may be employed in any circuit, hardware component, IC, or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

Implementation examples are described in the following numbered clauses:
1. An integrated circuit (IC) comprising:
   a memory bus interface configured to be coupled to a memory device through a memory bus; and
   a memory controller coupled to the memory bus interface and configured to: instruct the memory device to put active data in a memory segment; and set a segment mask for the memory segment.
2. The IC of clause 1, further comprising a processor coupled to the memory controller.
3. The IC of clause 2, wherein the processor comprises a neural signal processor (NSP).
4. The IC of clause 2, wherein the processor comprises a graphics processing unit (GPU).
5. The IC of clause 2, wherein the processor comprises a video encoder.
6. The IC of any of clauses 2 to 5, wherein the memory controller instructs responsive to a command from the processor.
7. The IC of either of clauses 2 or 6, wherein the processor comprises a neural processing unit (NPU).
8. The IC of any preceding clause, wherein the memory bus interface comprises a low power double data rate (LPDDR) bus interface.
9. The IC of any preceding clause, wherein the memory controller is further configured to instruct the memory device to refresh non-masked segments.
10. The IC of any preceding clause, wherein the segment mask comprises at least one partial array auto refresh (PAAR) bit.
11. The IC of clause 10, wherein the segment mask comprises a plurality of PAAR bits.
12. The IC of any of clauses 2 to 11, further comprising a timer associated with the processor.
13. The IC of clause 12, wherein the processor is configured to start the timer responsive to an event.
14. The IC of clause 13, wherein the processor is configured to restart the timer on reoccurrence of the event.
15. The IC of either of clauses 13 or 14, wherein the processor is configured to instruct the memory controller to instruct a refresh of masked segments when the timer expires without reoccurrence of the event.
16. The IC of any of clauses 2 to 15, wherein the processor is further configured to communicate with an application to provide a refresh interval to the application.
17. The IC of clause 16, wherein the refresh interval comprises a temperature-compensated refresh interval.
18. The IC of either of clauses 16 or 17, wherein the application reads or writes to the memory segment in each refresh interval.
19. The IC of any preceding clause, wherein the IC comprises a system on a chip (SoC).
20. The IC of any preceding clause, wherein the active data comprises a weight.
21. The IC of any of clauses 1 to 19, wherein the active data comprises an activation.
22. An integrated circuit (IC) comprising:
   a memory bus interface configured to be coupled to a memory controller through a memory bus; and
   a memory bank coupled to the memory bus interface and configured to:
      receive a sequence of commands to put active data in a memory segment; and
      set a segment mask for the memory segment.
23. A method for managing memory comprising:
   instructing a memory device to put active data in a memory segment; and
   setting a segment mask for the memory segment.
24. A method for managing memory comprising:
   at a memory bank, receiving a sequence of commands to put active data in a memory segment; and
   setting a segment mask for the memory segment.

What is claimed is:

1. An integrated circuit (IC) comprising:
a memory bus interface configured to be coupled to a memory device through a memory bus; and
a memory controller coupled to the memory bus interface and configured to:
instruct the memory device to put active data in a memory segment; and
set a segment mask for the memory segment.

2. The IC of claim 1, further comprising a processor coupled to the memory controller.

3. The IC of claim 2, wherein the processor comprises a neural signal processor (NSP).

4. The IC of claim 2, wherein the processor comprises a graphics processing unit (GPU).

5. The IC of claim 2, wherein the processor comprises a video encoder.

6. The IC of claim 2, wherein the memory controller instructs responsive to a command from the processor.

7. The IC of claim 2, wherein the processor comprises a neural processing unit (NPU).

8. The IC of claim 1, wherein the memory bus interface comprises a low power double data rate (LPDDR) bus interface.

9. The IC of claim 1, wherein the memory controller is further configured to instruct the memory device to refresh non-masked segments.

10. The IC of claim 1, wherein the segment mask comprises at least one partial array auto refresh (PAAR) bit.

11. The IC of claim 10, wherein the segment mask comprises a plurality of PAAR bits.

12. The IC of claim 2, further comprising a timer associated with the processor.

13. The IC of claim 12, wherein the processor is configured to start the timer responsive to an event.

14. The IC of claim 13, wherein the processor is configured to restart the timer on reoccurrence of the event.

15. The IC of claim 13, wherein the processor is configured to instruct the memory controller to instruct a refresh of masked segments when the timer expires without reoccurrence of the event.

16. The IC of claim 2, wherein the processor is further configured to communicate with an application to provide a refresh interval to the application.

17. The IC of claim 16, wherein the refresh interval comprises a temperature-compensated refresh interval.

18. The IC of claim 16, wherein the application reads or writes to the memory segment in each refresh interval.

19. The IC of claim 1, wherein the IC comprises a system on a chip (SoC).

20. The IC of claim 1, wherein the active data comprises a weight.

21. The IC of claim 1, wherein the active data comprises an activation.

22. An integrated circuit (IC) comprising:
a memory bus interface configured to be coupled to a memory controller through a memory bus; and
a memory bank coupled to the memory bus interface and configured to:
receive a sequence of commands to put active data in a memory segment; and
set a segment mask for the memory segment.

23. A method for managing memory comprising:
instructing a memory device to put active data in a memory segment; and
setting a segment mask for the memory segment.

24. A method for managing memory comprising:
at a memory bank, receiving a sequence of commands to put active data in a memory segment; and
setting a segment mask for the memory segment.
